(19) United States
(12) Patent Application Publication
(10) Pub. No.: US 2022/0355438 A1
(43) Pub. Date: Nov. 10, 2022

(54) GRINDING WHEEL JIG

(71) Applicant: DISCO CORPORATION, Tokyo (JP)

(72) Inventors: Yuto MAEDA, Tokyo (JP); Atsushi NAKATSUKA, Tokyo (JP)

(21) Appl. No.: 17/660,455

(22) Filed: Apr. 25, 2022

(30) Foreign Application Priority Data
May 10, 2021 (JP) 2021-079935

(51) Int. Cl. B24B 45/00; B24B 37/04

(52) U.S. Cl. CPC B24B 45/003; B24B 37/04

(57) ABSTRACT

A grinding wheel jig includes a bottomed cylindrical grindstone accommodating section that accommodates the annular grindstone section, an annular base accommodating section that is located on a side opposite to a bottom portion of the grindstone accommodating section in a height direction of the grindstone accommodating section, has an outside diameter greater than an outside diameter of the grindstone accommodating section, and is capable of accommodating at least a part of the base, and a plurality of cylindrical bolt accommodating sections provided at bottom portions of the base accommodating sections and each capable of accommodating a head part of a bolt. In the grinding wheel jig, each bolt accommodating section is provided, at a bottom portion thereof, with an opening in which a fastening tool is insertable into the head part of the bolt.

### BACKGROUND OF THE INVENTION

### Field of the Invention

The present invention relates to a grinding wheel jig used when a grinding wheel is mounted to a lower surface side of a disk-shaped mount attached to a lower end portion of a spindle and to a grinding wheel case that accommodates a grinding wheel.

### Description of the Related Art

At the time of grinding a workpiece such as a silicon wafer, a grinding apparatus is used. The grinding apparatus includes a grinding unit including a cylindrical spindle. The spindle is disposed, for example, substantially parallel to the vertical direction, and a disk-shaped mount (wheel mount) is fixed to a lower end portion of the spindle. An annular grinding wheel is mounted to a lower surface side of the mount.

In a normal grinding apparatus used at the time of grinding the whole of a back surface side (namely, the side opposite to a front surface formed with devices) of the workpiece, a normal grinding wheel having an annular base (wheel base) is mounted to the abovementioned mount. At a peripheral part of the mount, a plurality of through-holes are provided along the circumferential direction of the mount, and, at a peripheral part on one surface side (namely, the side opposite to the other surface provided with grindstones) of a base of the normal grinding wheel, a plurality of screw holes are provided along the circumferential direction of the base in such a manner as to correspond to each through-hole.

At the time of mounting the normal grinding wheel to the mount, a bolt is inserted into each through-hole of the mount from the upper side of the mount, and a lower end portion of each bolt is fastened to a screw hole of the grinding wheel. In addition, at the time of detaching the mount from the grinding wheel, each bolt is detached from the upper side of the mount. At the time of attaching and detaching such a normal grinding wheel to and from the mount, use of a jig having an annular recess capable of covering the whole of a side part and a lower part of the grinding wheel, for protecting the grindstones and the like, has been known (see, for example, Japanese Patent Laid-open No. 2011-121128).

Incidentally, while a circular predetermined area on the back surface side of the workpiece corresponding to the device area provided on the front surface side of the workpiece is ground, grinding called TAIKO (registered trademark in Japan, United States of America, Republic of Singapore, etc.) in which a peripheral part on the back surface side is not ground but left, to form a disk-shaped recess on the back surface side, has been known. In the case of performing this grinding, a dedicated grinding apparatus different from the normal grinding apparatus is used. In the dedicated grinding apparatus, a peripheral part on the lower surface side of the mount is provided with a plurality of screw holes along the circumferential direction of the mount. In addition, a grinding wheel base (wheel base) mounted to the mount has an annular flange, and, at a peripheral part on the lower surface side of the flange, a plurality of through-holes are provided along the circumferential direction of the flange.

On the lower surface side of the flange and on the center side of the flange relative to the plurality of through-holes, an annular grindstone mounted section smaller in diameter than the flange is fixed concentrically with the flange. On the lower surface side of the grindstone mounted section, a plurality of grindstones each segment-shaped are disposed along the circumferential direction of the base. To mount such a grinding wheel to the mount, first, the grinding wheel is disposed on a lower side of the mount, and the through-holes of the flange and the screw holes of the mount are aligned. In this state, the bolts are inserted into the mount from the lower surface side of the flange, and each bolt is fastened to the screw hole of the mount.

### SUMMARY OF THE INVENTION

However, when a jig for covering the whole of a side portion and a lower portion of the grinding wheel is used like a jig for a normal grinding wheel, insertion of the bolt into the through-hole and the screw hole from the lower side of the mount is hampered by the jig. On the other hand, in the case where the jig is not used, the hand of the operator may touch the grindstones, possibly being injured, or the grindstones may be damaged due to contact with a tool. In addition, cutting swarf deposited on the grindstones or the like may fall, possibly contaminating the inside of the grinding apparatus.

The present invention has been made in consideration of such problems. It is an object of the present invention to provide a grinding wheel jig capable of inserting the bolt from the lower side of the mount at the time of mounting the grinding wheel to the mount.

In accordance with an aspect of the present invention, there is provided a grinding wheel jig used when a grinding wheel having an annular grindstone section disposed on one surface side of an annular base is mounted to a lower surface side of a disk-shaped mount attached to a lower end portion of a spindle, the grinding wheel jig including a bottomed cylindrical grindstone accommodating section that accommodates the annular grindstone section, an annular base accommodating section that is located on a side opposite to a bottom portion of the grindstone accommodating section in a height direction of the grindstone accommodating section, has an outside diameter greater than an outside diameter of the grindstone accommodating section, and is capable of accommodating at least a part of the base, and a plurality of cylindrical bolt accommodating sections provided at a bottom portion of the base accommodating section and each capable of accommodating a head part of a bolt. In the grinding wheel jig, each bolt accommodating section is provided, at a bottom portion thereof, with an opening in which a fastening tool is insertable into the head part of the bolt.

Preferably, an inner circumferential side surface of a side part of the base accommodating section makes contact with an outer circumferential side surface of the mount when the base accommodated in the base accommodating section is made to make contact with the lower surface of the mount.

In accordance with another aspect of the present invention, there is provided a grinding wheel case that accommodates a grinding wheel having an annular grindstone section disposed on one surface side of an annular base, the grinding wheel case including a grinding wheel jig including a bottomed cylindrical grindstone accommodating section that accommodates the annular grindstone section, an annular base accommodating section that is located on a side opposite to a bottom portion of the grindstone accommodating section in a height direction of the grindstone accommodating section, has an outside diameter greater than an outside diameter of the grindstone accommodating section, and is capable of accommodating at least a part of the base, and a plurality of cylindrical bolt accommodating sections provided at a bottom portion of the base accommodating section and each capable of accommodating a head part of a bolt, each bolt accommodating section being provided, in a bottom portion thereof, with an opening in which a fastening tool is insertable into the head part of the bolt, and a lid section that closes the opening of the base accommodating section.

The grinding wheel jig according to one mode of the present invention has a grindstone accommodating section that accommodate an annular grindstone section. In the height direction of the grindstone accommodating section, an annular base accommodating section is located on a side opposite to a bottom portion of the grindstone accommodating section. The base accommodating section has an outside diameter greater than an outside diameter of the grindstone accommodating section and is capable of accommodating at least a part of the base. At a bottom portion of the base accommodating section, a plurality of cylindrical bolt accommodating sections are provided. Each bolt accommodating section is provided, in a bottom portion thereof, with an insertion hole in which a fastening tool is insertable into the head part of the bolt.

Accordingly, inserting the bolt into the through-hole of the base from a lower side of the mount and fastening the bolt into the screw hole of the mount in a state in which the grinding wheel is accommodated in the grinding wheel jig makes it possible to mount the grinding wheel to the mount. Further, since the grindstone section is accommodated in the grindstone accommodating section, touch of the operator on the grindstone section, damage to the grindstone section by a tool, drop of the cutting swarf from the grindstone section or the base, or the like, at the time of attaching or detaching the grinding wheel, can be prevented.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a side view of a grinding unit;

FIG. 2A is a perspective view of a workpiece;

FIG. 2B is a sectional view of the workpiece obtained after grinding;

FIG. 3A is a perspective view of an upper portion side of a jig;

FIG. 3B is an enlarged view of an alternate long and short dash line region of FIG. 3A;

FIG. 4A is a perspective view of a lower portion side of the jig;

FIG. 4B is an enlarged view of an alternate long and short dash line region of FIG. 4A;

FIG. 5 is a lower perspective view of a grinding wheel accommodated in the jig;

FIG. 6 is an upper perspective view of the grinding wheel accommodated in the jig;

FIG. 7 is a partially sectional side view depicting the manner of mounting a grinding wheel to a mount;

FIG. 8 is a partially sectional side view of a case;

FIG. 9 is a side view of a jig according to a second embodiment;

FIG. 10A is a side view of the mount;

FIG. 10B is a partially sectional side view of the mount;

FIG. 10C is a bottom view of the mount;

FIG. 11A is a diagram depicting the manner in which the grinding wheel is raised; and

FIG. 11B is a diagram depicting the manner in which the grinding wheel is rotated.

### DETAILED DESCRIPTION OF THE PREFERRED EMBODIMENTS

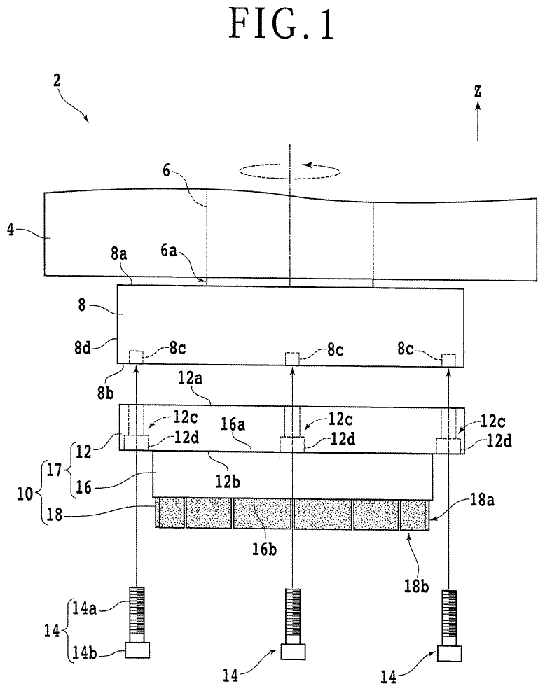

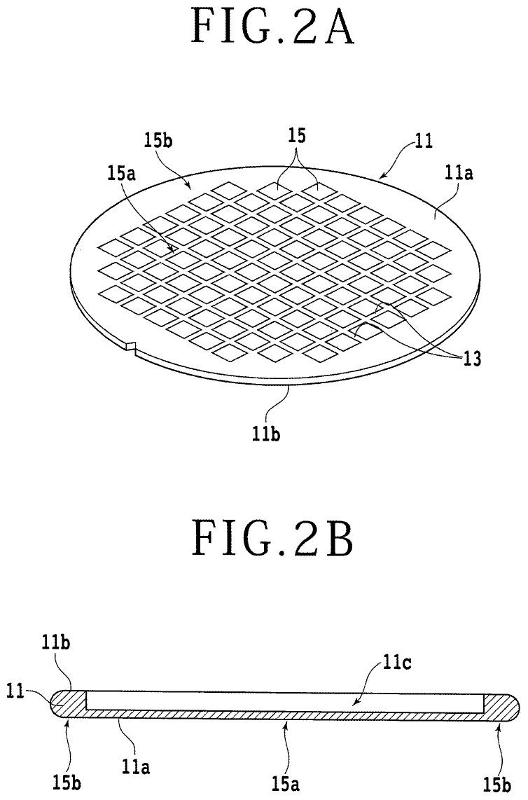

An embodiment according to one mode of the present invention will be described referring to the attached drawings. First, a grinding unit 2 to which a grinding wheel 10 is mounted will be described. FIG. 1 is a side view of the grinding unit 2. Note that a Z-axis direction depicted in FIG. 1 is, for example, parallel to the vertical direction. The grinding unit 2 is used at the time of grinding a back surface 11b side of a disk-shaped workpiece 11 (see FIG. 2A).

FIG. 2A is a perspective view of the workpiece 11. The workpiece 11 is, for example, a disk-shaped silicon wafer. On a front surface 11a side of the workpiece 11, a plurality of streets 13 are set in a grid pattern. In each of regions partitioned by the plurality of streets 13, a device 15 such as an integrated circuit (IC) is formed. In the surroundings of a device area 15a where a plurality of devices 15 are formed, a peripheral marginal area 15b in which the devices 15 are not formed and which is substantially flat is present. The grinding unit 2 is used when grinding a circular area on a back surface 11b side of the workpiece 11 corresponding to the device area 15a to form a recess 11c (see FIG. 2B). FIG. 2B is a sectional view of the workpiece 11 obtained after grinding.

Described with reference to FIG. 1 again, the grinding unit 2 has a cylindrical spindle housing 4. The spindle housing 4 is movable along the Z-axis direction by a ball screw type grinding feeding unit (not illustrated). A part of a cylindrical spindle 6 is rotatably accommodated in the spindle housing 4. A rotational drive source (not illustrated) such as a motor is provided at an upper end portion of the spindle 6. A lower end portion 6a of the spindle 6 is projected to a portion lower than a bottom portion of the spindle housing 4, and a central portion on an upper surface 8a side of a disk-shaped mount 8 is attached to the lower end portion 6a.

On a lower surface 8b side of the mount 8, a plurality of screw holes 8c are provided at substantially regular intervals along the circumferential direction of the mount 8. In the present embodiment, four screw holes 8c are provided along the circumferential direction of the mount 8. It is to be noted, however, that three screw holes 8c are depicted in FIG. 1. An annular grinding wheel 10 is mounted to the lower surface 8b side of the mount 8. The grinding wheel 10 is formed of a metallic material such as an aluminum alloy and stainless steel. The grinding wheel 10 has an annular flange 12 roughly equal in outside diameter to the mount 8.

At a peripheral portion of the flange 12, a plurality of through-holes 12c penetrating the flange 12 from the upper surface 12a to the lower surface 12b of the flange 12 are formed. The plurality of through-holes 12c are spaced substantially regularly along the circumferential direction of the flange 12. In the present embodiment, four through-holes 12c are provided along the circumferential direction of the flange 12. It is to be noted, however, that three through-holes 12c are depicted in FIG. 1. As the screw holes 8c and the through-holes 12c correspond one to one, after the flange 12 is disposed on the mount 8, shaft sections 14a of the bolts 14 are inserted in the through-holes 12c, and the shaft sections 14a are fastened to the screw holes 8c. Note that, on the lower surface 12b side of the through-holes 12c, a counterbored section 12d capable of accommodating the head part 14b of the bolt 14 is formed. The bolt 14 of the present embodiment is a hexagonal holed bolt formed with a hexagonal hole in the head part 14b. In addition, the outside diameter of the shaft section 14a is 5 mm.

On the lower surface 12b side of the flange 12 and on the inner side than the periphery of the flange 12, an annular grindstone mounted section 16 formed of the same metallic material as the flange 12 is fixed. The grindstone mounted section 16 has an outside diameter smaller than that of the flange 12, and is disposed substantially concentrically with the flange 12. An upper surface 16a side of the grindstone mounted section 16 is fixed to the lower surface 12b side of the flange 12. Herein, the grindstone mounted section 16 and the flange 12 together are called a base (wheel base) 17. On the lower surface (one surface) 16b side of the grindstone mounted section 16, a plurality of grindstones (grindstone sections) 18, each in a segment form, are disposed in an annular pattern along the circumferential direction of the grindstone mounted section 16. Note that the annular grindstone section may be one annular (what is generally called a continuous type) grindstone.

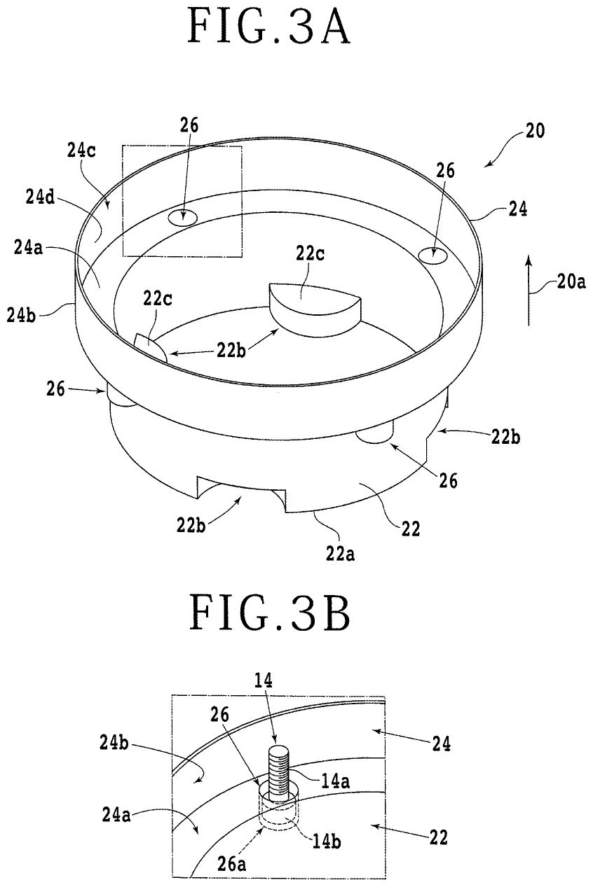

At the time of mounting the grinding wheel 10 to the mount 8, as depicted in FIG. 1, first, the grinding wheel 10 is disposed under the mount 8, and the through-holes 12c of the flange 12 and the screw holes 8c of the mount 8 are aligned. In this state, the bolt 14 is inserted into the through-hole 12c from the lower surface 12b side of the flange 12, and each bolt 14 is fastened to the screw hole 8c of the mount 8. In the present embodiment, at the time of mounting the grinding wheel 10 to the mount 8, a jig (grinding wheel jig) 20 capable of inserting the bolt 14 from the lower side of the mount 8 is used (see FIG. 3A).

FIG. 3A is a perspective view of an upper part side of the jig 20. The jig 20 of the present embodiment is formed of a translucent resin, but the jig 20 may be formed of a transparent resin or may be formed of a non-translucent resin or other material. The jig 20 of the present embodiment can be produced, for example, by a three-dimensional (3D) printer, but may be produced by a device other than the 3D printer. The jig 20 has a bottomed cylindrical grindstone accommodating section 22. The outside diameter of the cylinder of the grindstone accommodating section 22 of the present embodiment is 102 mm, and the length of the grindstone accommodating section 22 in a height direction 20a of the jig 20 (that is, in the height direction of the base accommodating section 24) is 37 mm.

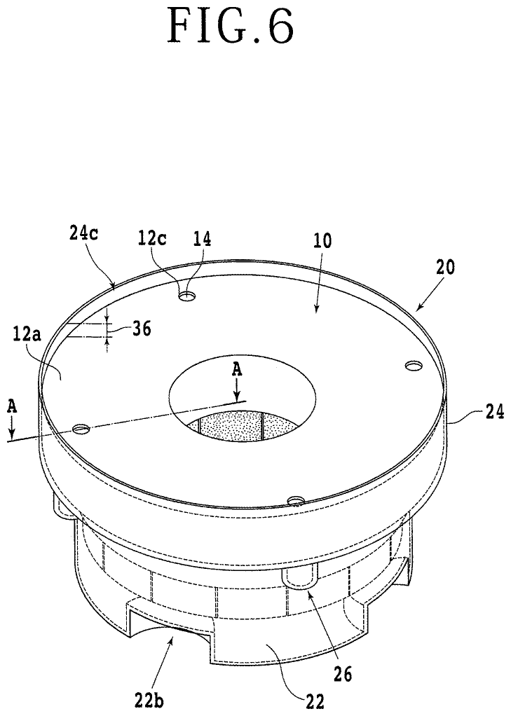

The grindstone accommodating section 22 covers the whole body of an outer circumferential side surface 18a and a lower surface 18b (see FIG. 1) of each grindstone 18, thereby accommodating the plurality of grindstones 18. On the bottom portion 22a side of the grindstone accommodating section 22, a substantially semicylindrical recess 22b is formed in the manner of being recessed toward the center side in the radial direction of the grindstone accommodating section 22. In the present embodiment, four recesses 22b are formed at substantially regular intervals along the circumferential direction of the grindstone accommodating section 22. It is to be noted, however, that the number of the recesses 22b is not limited to four. Note that, in a state in which the grinding wheel 10 is accommodated in the jig 20, the lower surface 18b of the grindstone 18 does not make contact with an upper surface 22c of the recess 22b (see FIG. 6). The recess 22b is provided for the purpose of easy handling of the jig 20 when the operator holds the jig 20 by hand. For example, the recess 22b facilitates movement or rotation of the jig 20.

In the height direction 20a of the jig 20, an annular base accommodating section 24 having an outside diameter greater than the outside diameter of the grindstone accommodating section 22 is connected to a top part located on the side opposite to the bottom portion 22a. The base accommodating section 24 has an annular bottom portion 24a connected to the outside of the top part of the grindstone accommodating section 22. At a peripheral part of the bottom portion 24a, an annular side portion 24b is provided in such a manner as to project in the height direction 20a. The side portion 24b and the bottom portion 24a each have substantially the same thickness as the grindstone accommodating section 22. The top side of the base accommodating section 24 is an opening 24c. The outside diameter of the base accommodating section 24 of the present embodiment is 124 mm, and the length of the base accommodating section 24 in the height direction 20a is 20 mm.

At the bottom portion 24a of the base accommodating section 24, a plurality of cylindrical bolt accommodating sections 26 are provided at substantially regular intervals along the circumferential direction of the base accommodating section 24. While four bolt accommodating sections 26 are provided in the present embodiment, the number of the bolt accommodating sections 26 may appropriately be changed according to the number of the screw holes 8c. One bolt accommodating section 26 is located between the two recesses 22b when the jig 20 is viewed in plan. The bolt accommodating section 26 includes a cylindrical recess that has a diameter roughly equal to the outside diameter of the head part 14b of the bolt 14. A bottom portion 26a of each bolt accommodating section 26 is projected toward the bottom portion 22a side of the grindstone accommodating section 22 than the bottom portion 24a of the base accommodating section 24.

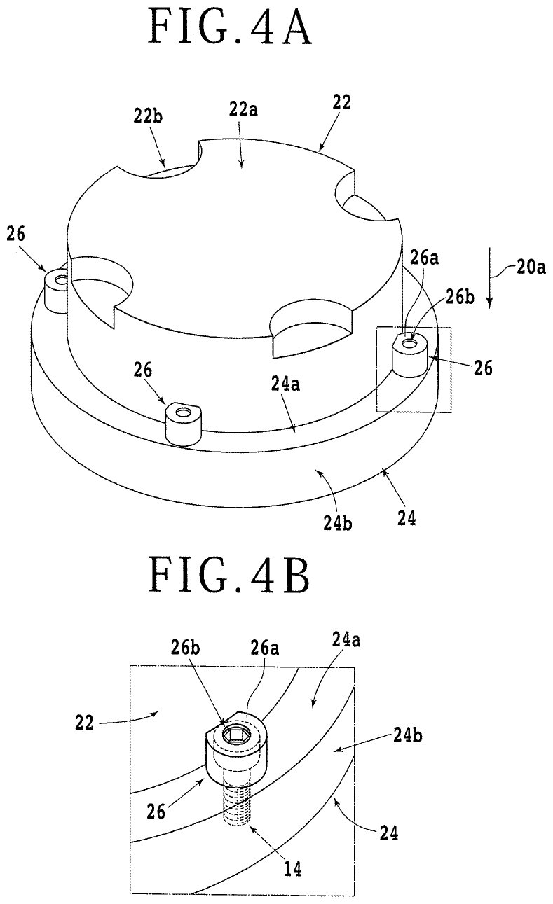

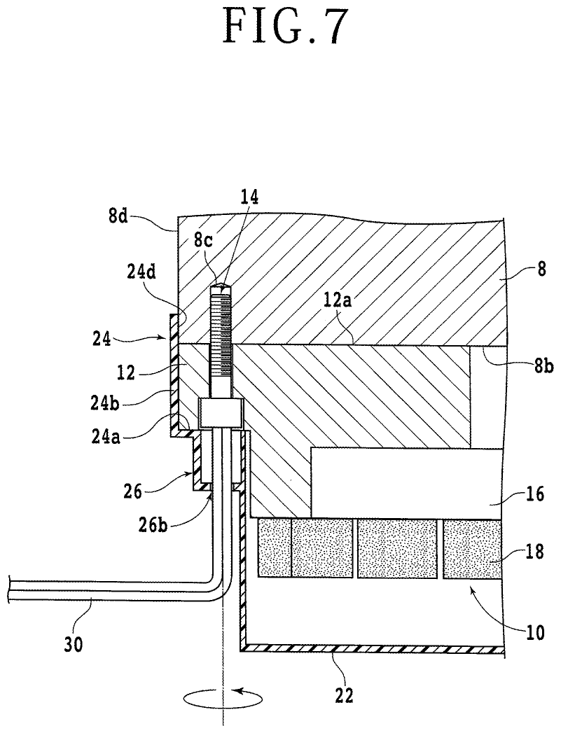

As depicted in FIG. 3B, when the head part 14b is supported by the bottom portion 26a of the bolt accommodating section 26 and the whole of the head part 14b is accommodated in the bolt accommodating section 26, the shaft section 14a projects in the height direction 20a from the bolt accommodating section 26. FIG. 3B is an enlarged view of an alternate long and short dash line region of FIG. 3A, and depicts a state in which the bolt 14 is accommodated in the bolt accommodating section 26. A circular opening 26b (see FIGS. 4A and 4B) is formed in the bottom portion 26a of the bolt accommodating section 26. For example, through the opening 26b, a hexagonal wrench (fastening tool) 30 (see FIG. 7) is inserted into a hexagonal hole at the head part 14b of the bolt 14. While the hexagonal hole is formed in the head part 14b in the present embodiment, in the case where a cross hole or a tetragonal hole is formed in place of the hexagonal hole in the head part 14b, the fastening tool is appropriately selected according to the shape of the hole.

FIG. 4A is a perspective view of a lower portion side of the jig 20, and FIG. 4B is an enlarged view of an alternate long and short dash line region of FIG. 4A. Note that, in FIG. 4B, for the sake of convenience, depicted is the bolt 14 accommodated in the bolt accommodating section 26 in a state in which the head part 14b is in contact with the bottom portion 26a. The grinding wheel 10 is accommodated in the jig 20 in a state in which the bolt 14 is inserted in each through-hole 12c in the flange 12 of the grinding wheel 10.

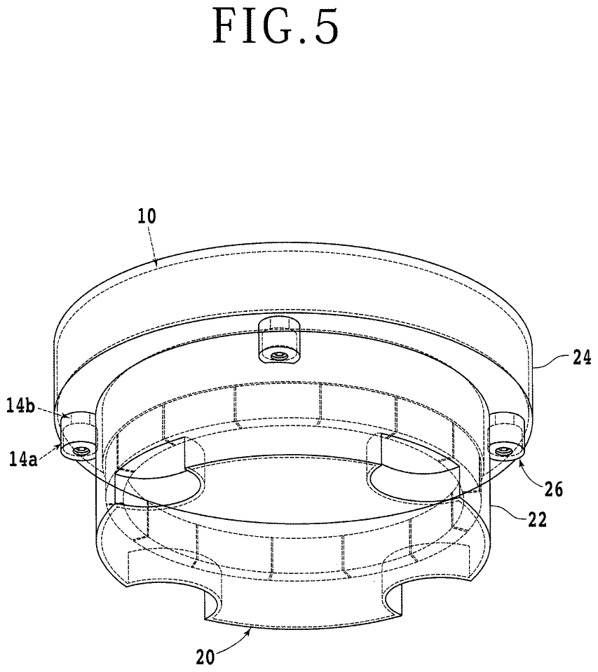

FIG. 5 is a lower-side perspective view of the grinding wheel 10 accommodated in the jig 20. As depicted in FIG. 5, when the grinding wheel 10 is accommodated in the jig 20, the lower surface 12b of the flange 12 is supported by the bottom portion 24a of the base accommodating section 24, and the head part 14b of the bolt 14 is supported by the bottom portion 26a of the bolt accommodating section 26.

In this instance, as depicted in FIG. 6, the upper surface 12a of the flange 12 does not project from the opening 24c. In addition, an outer circumferential side surface of the flange 12 makes contact with the inner circumferential side surface 24d (see FIG. 7) of the side portion 24b of the base accommodating section 24. FIG. 6 is an upper-side perspective view of the grinding wheel 10 accommodated in the jig 20. Note that, as depicted in FIG. 6, when the bolt 14 is accommodated in the bolt accommodating section 26, the shaft section 14a of the bolt 14 does not project from the upper surface 12a.

Next, the procedure of mounting the grinding wheel 10 accommodated in the jig 20 to the mount 8 will be described. First, the operator holds the jig 20 by hand, the screw hole 8c and the through-hole 12c are adjusted in such a direction as to correspond one to one, the jig 20 is raised, and the upper surface 12a of the flange 12 is brought into contact with the lower surface 8b of the mount 8. In this instance, an upper portion of the inner circumferential side surface 24d of the side portion 24b makes contact with the outer circumferential side surface 8d of the mount 8, and hence, the rotational center of the grinding wheel 10 and the rotational center of the mount 8 can easily be aligned. In addition, aligning the position of the bolt accommodating section 26 with the screw hole 8c in a state in which the mount 8 is viewed in side elevation makes it possible to easily align the bolt 14 and the screw hole 8c.

Next, the hexagonal wrench 30 is inserted into the opening 26b, and each bolt 14 is fastened to the screw hole 8c, whereby the grinding wheel 10 is mounted to the mount 8 (see FIG. 7). FIG. 7 is a partially sectional side view depicting the manner of mounting the grinding wheel 10 to the mount 8. Note that, after the grinding wheel 10 is mounted, the jig 20 is detached from the grinding wheel 10.

In the present embodiment, in a state in which the grinding wheel 10 is accommodated in the jig 20, the bolt 14 is fastened to the screw hole 8c from the lower side of the mount 8, whereby the grinding wheel 10 can be mounted to the mount 8. Further, since a plurality of grindstones 18 are accommodated in the grindstone accommodating section 22, contact of the operator with the grindstones 18, damage to the grindstones 18 by a tool, dropping of cutting swarf from the grindstones 18 or the base 17, or the like, at the time of attaching or detaching the grinding wheel 10, can be prevented.

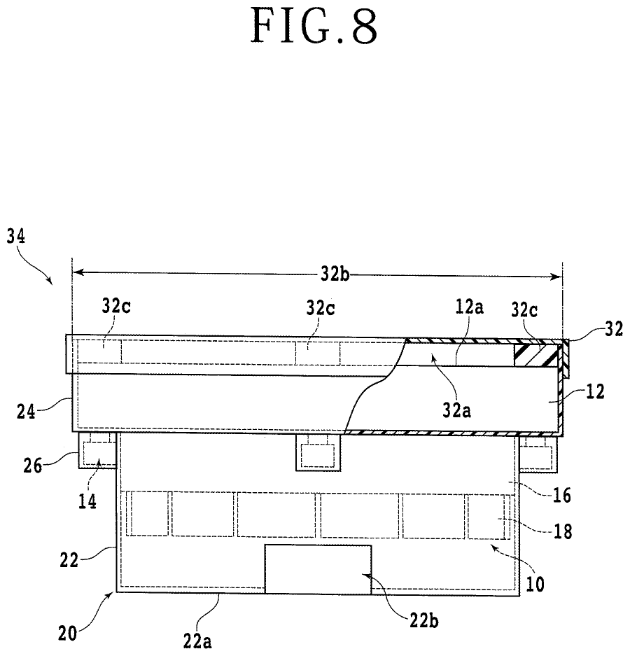

Incidentally, at the time of detaching the grinding wheel 10, the procedure reverse to that of mounting is performed. In other words, in a state in which the jig 20 is mounted to the grinding wheel 10 from a lower side, each bolt 14 is detached. Thereafter, in a state in which the grinding wheel 10 is accommodated in the jig 20, the grinding wheel 10 is detached from the mount 8. As depicted in FIG. 8, the grinding wheel 10 detached from the mount 8 is stored in the state of being accommodated in a case (grinding wheel case) 34 composed of the jig 20 and a disk-shaped lid section 32.

FIG. 8 is a partially sectional side view of the case 34. The lid section 32 of the present embodiment is formed of the same material as the jig 20, but the lid section 32 may be formed of a material different from that of the jig 20. The lid section 32 has a disk-shaped recess 32a on the inside. A diameter 32b of the recess 32a is roughly equal to the outside diameter of the side portion 24b of the base accommodating section 24, and, hence, the lid section 32 can be fitted to an upper portion side of the base accommodating section 24 in such a manner as to close the opening 24c of the base accommodating section 24. With the opening 24c closed by the lid section 32, the grinding wheel 10 and the plurality of bolts 14 can integrally be accommodated in the case 34.

At the recess 32a, a plurality of cylindrical spacers 32c formed of resin are disposed along the circumferential direction of the lid section 32. In the present embodiment, four spacers 32c are disposed roughly at regular intervals along the circumferential direction of the lid section 32. It is to be noted, however, that three spacers 32c are depicted in FIG. 8. The height (thickness) of each spacer 32c corresponds to a depth 36 (see FIG. 6) from the opening 24c to the upper surface 12a in the case where the grinding wheel 10 is accommodated in the jig 20.

The diameter of the spacers 32c in the present embodiment is greater than that of the through-hole 12c of the flange 12 such that the spacers 32c are not fitted in the through-holes 12c. With the spacers 32c provided, movement in the case 34 of the grinding wheel 10 accommodated in the case 34 can be restrained. Note that, in place of the cylindrical spacers 32c, one ring-shaped spacer (not illustrated) may be provided concentrically with the lid section 32, or a plurality of arcuate spacers (not illustrated) may be provided along the circumferential direction of the lid section 32.

Incidentally, the grinding wheels 10 have different diameters according to the diameter of the workpiece 11. In addition, jigs 20 with different diameters are used according to the diameter of the grinding wheel 10. Hence, in the case where the jig 20 is used only at the time of attaching and detaching the grinding wheel 10 to and from the mount 8, it may be necessary to search for the jig 20 according to the diameter of the grinding wheel 10 each time. However, as described above, if the grinding wheel 10 is accommodated in the case 34, the grinding wheel 10 can be mounted to the mount 8 by use of the jig 20 having the diameter according to the grinding wheel 10 by only detaching the lid section 32, so that there is an advantage of easy management of the jig 20. Further, there is also an advantage that the bolt 14 being lost can be prevented.

Note that, at an inner circumferential side surface of the lid section 32 and at an outer circumferential side surface of the side portion 24b, an engaging mechanism (not illustrated) like a screw cap for fixing the lid section 32 and the base accommodating section 24 by rotation may be provided. In addition, in place of the engaging mechanism, a different fixing mechanism may be provided.

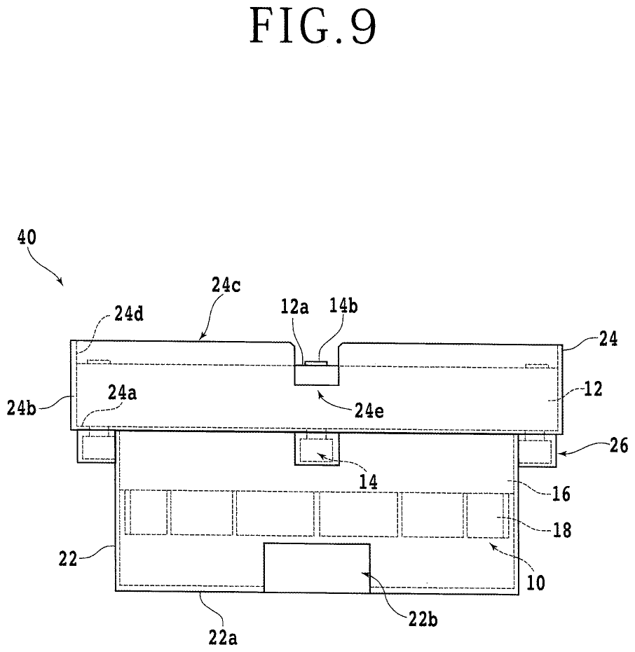

Next, a second embodiment will be described. FIG. 9 is a side view of a jig (grinding wheel jig) 40 according to the second embodiment. Hereinafter, difference between the jig 40 and the jig 20 will mainly be described. The depth of the recess of the bolt accommodating section 26 of the jig 40 is shallower than that of the bolt accommodating section 26 of the first embodiment. Hence, the bolt 14 accommodated in the bolt accommodating section 26 of the second embodiment has a tip portion of the shaft section 14a thereof projecting from the upper surface 12a of the flange 12.

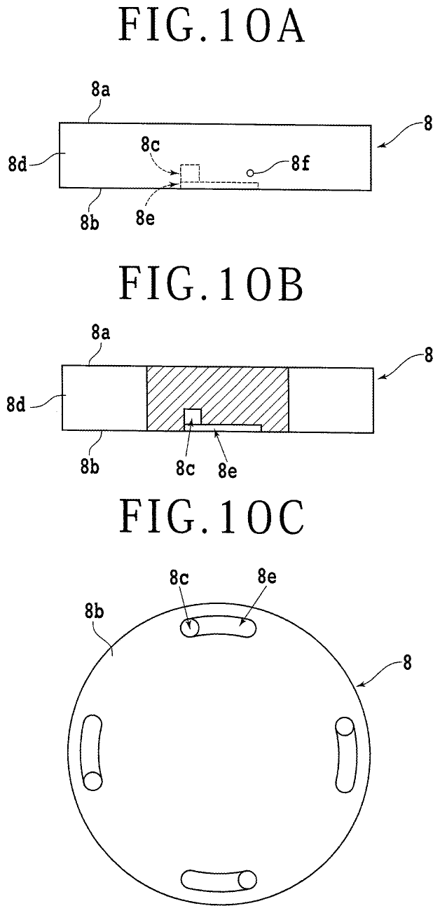

The side portion 24b of the base accommodating section 24 is formed with a plurality of rectangular cutouts 24e. Since each cutout 24e is located at a position corresponding to the bolt accommodating section 26, the operator can visually recognize, from a lateral side of the jig 40, a tip portion of the shaft section 14a projecting from the upper surface 12a. The jig 40 is used when the grinding wheel 10 is to be mounted to the mount 8 by rotation. The mount 8 used in the second embodiment includes, on the lower surface 8b side relative to the screw hole 8c, an arcuate long groove 8e having substantially the same width as the screw hole 8c (see FIGS. 10A to 10C).

FIG. 10A is a side view of the mount 8 according to the second embodiment, FIG. 10B is a partially sectional side view of the mount 8 according to the second embodiment, and FIG. 10C is a bottom view of the mount 8 according to the second embodiment. Of the outer circumferential side surface 8d, a predetermined position corresponding to one end portion of the long groove 8e has a mark 8f applied thereto. The mark 8f is, for example, engraved by laser processing. At an upper portion of the other end portion of the long groove 8e, the abovementioned screw hole 8c is provided. At the time of mounting the grinding wheel 10 to the mount 8, the operator adjusts the direction of the jig 40 accommodating the grinding wheel 10 such that the mark 8f and the tip of the shaft section 14a of the bolt 14 correspond to each other, and raises the jig 40.

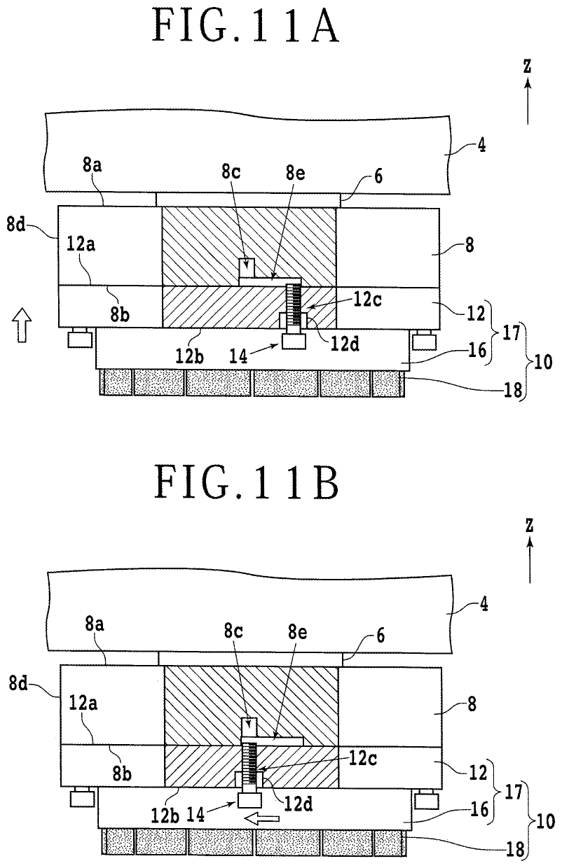

FIG. 11A is a diagram depicting the manner in which the grinding wheel 10 is raised relative to the mount 8, such that the upper surface 12a of the flange 12 makes contact with the lower surface 8b of the mount 8. Note that, while the jig 40 is used in this instance, in FIG. 11A the jig 40 is omitted from illustration for the sake of convenience. At the time of raising the grinding wheel 10, an upper portion of the inner circumferential side surface 24d of the side portion 24b of the jig 40 makes contact with the outer circumferential side surface 8d of the mount 8, so that the rotational center of the grinding wheel 10 and the rotational center of the mount 8 can easily be aligned. When the upper surface 12a of the flange 12 makes contact with the lower surface 8b of the mount 8, the shaft section 14a fits into the long groove 8e.

Thereafter, as depicted in FIG. 11B, the grinding wheel 10 is rotated in a predetermined direction together with the jig 40, and the bolt 14 is disposed on the lower side of the screw hole 8c. FIG. 11B is a diagram depicting the manner in which the grinding wheel 10 is rotated relative to the mount 8 until the bolt 14 is located directly below the screw hole 8c. Note that, also in FIG. 11B, the jig 40 is omitted from illustration for the sake of convenience. After the grinding wheel 10 is rotated, each bolt 14 is fastened to the screw hole 8c by use of the hexagonal wrench 30, as in FIG. 7.

In the second embodiment, also, fastening the bolt 14 into the screw hole 8c from the lower side of the mount 8 in a state in which the grinding wheel 10 is accommodated in the jig 40 makes it possible to mount the grinding wheel 10 to the mount 8. Further, since the plurality of grindstones 18 are accommodated in the grindstone accommodating section 22, contact of the operator with the grindstones 18, damage to the grindstones 18 by a tool, and dropping of cutting swarf from the grindstones 18 or the base 17, or the like, at the time of attaching or detaching the grinding wheel 10, can be prevented.

Other than the above, the structures, methods, and the like according to the abovementioned embodiments can appropriately be modified in carrying out the present invention insofar as the modifications do not depart from the scope of the object of the invention. For example, the jig 40 of the second embodiment and the lid section 32 may constitute the case for the grinding wheel 10.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A grinding wheel jig used when a grinding wheel having an annular grindstone section disposed on one surface side of an annular base is mounted to a lower surface side of a disk-shaped mount attached to a lower end portion of a spindle,
the grinding wheel jig comprising:
a bottomed cylindrical grindstone accommodating section that accommodates the annular grindstone section;
an annular base accommodating section that is located on a side opposite to a bottom portion of the grindstone accommodating section in a height direction of the grindstone accommodating section, has an outside diameter greater than an outside diameter of the grindstone accommodating section, and is capable of accommodating at least a part of the base; and
a plurality of cylindrical bolt accommodating sections provided at a bottom portion of the base accommodating section and each capable of accommodating a head part of a bolt,
wherein each bolt accommodating section is provided, at a bottom portion thereof, with an opening in which a fastening tool is insertable into the head part of the bolt.

2. The grinding wheel jig according to claim 1, wherein an inner circumferential side surface of a side part of the base accommodating section makes contact with an outer circumferential side surface of the mount when the base accommodated in the base accommodating section is made to make contact with the lower surface of the mount.

3. A grinding wheel case that accommodates a grinding wheel having an annular grindstone section disposed on one surface side of an annular base,
the grinding wheel case comprising:
a grinding wheel jig including a bottomed cylindrical grindstone accommodating section that accommodates the annular grindstone section, an annular base accommodating section that is located on a side opposite to a bottom portion of the grindstone accommodating section in a height direction of the grindstone accommodating section, has an outside diameter greater than an outside diameter of the grindstone accommodating section, and is capable of accommodating at least a part of the base, and a plurality of cylindrical bolt accommodating sections provided at a bottom portion of the base accommodating section and each capable of accommodating a head part of a bolt, each bolt accommodating section being provided, at a bottom portion thereof, with an opening in which a fastening tool is insertable into the head part of the bolt; and
a lid section that closes the opening of the base accommodating section.
